(19) United States
(12) Patent Application Publication
(10) Pub. No.: US 2016/0374174 A1
(43) Pub. Date: Dec. 22, 2016

(54) OLED DEVICE WITH SHORT DETECTION CIRCUIT USING TEMPERATURE MEASUREMENT

(71) Applicant: OLEDWORKS GMBH, Aachen (DE)

(72) Inventor: Dirk HENTE, Würselen (DE)

(73) Assignee: OLEDWORKS GMBH, Aachen (DE)

(21) Appl. No.: 15/117,367

(22) PCT Filed: Jan. 28, 2015
(86) PCT No.: PCT/EP2015/051635

§ 371 Date: Aug. 9, 2016

(30) Foreign Application Priority Data
Feb. 10, 2014 (EP) 14154499.9

(51) Int. Cl. H05B 33/08; H05B 37/02

(52) U.S. Cl. CPC H05B 33/0896; H05B 37/0227; H01L 51/524

(57) ABSTRACT

The present invention relates to an MID device (51) comprising an OLED (52) and a short detection circuit (53) for detection a short in the OLED (52). The short detection circuit (53) comprise a temperature sensing unit (55) tar sensing a first and a second temperature of the OLED (52) and a short detection unit (56) kw detecting the short based on a difference between the first and the second temperature. Therewith, the short detection can be less sensitive with respect to production tolerances resp. OLED binning.

### FIELD OF THE INVENTION

The present invention relates to an organic light-emitting diode (OLED) device comprising an OLED and a short detection circuit for detection a short in the OLED. Further, the present invention relates to a corresponding short detection circuit and a corresponding short detection method for detecting, a short in an OLED. Yet further, the present invention relates to a corresponding lighting system comprising the OLED device.

### BACKGROUND OF THE INVENTION

OLEDs, in particular, large area OLEDs, are prone to shorts due to small particles contaminating the OLED substrate and or layers in case of imperfect cleaning and handling during production. Since, in practice, not all detects can be detected in the final production quality control, the occurrence of small shorts during operation may not always be avoided.

The detection of such shorts in the light-emitting area of an OLED is important, because they may result in a significant increase in the temperature at the locations of the defects (known also as “hot spot” effects). This is due to the fact that the power distribution, which is substantially evenly distributed across the light-emitting area during normal operation, may be concentrated at a very small area in case of a short. The local temperature at a hot spot can easily reach values well above 100 degrees Celsius, which can damage the OLED and or can even be dangerous to a human being.

Prior art methods for short detection are based on monitoring the OLED voltage as an indicator for the presence of a short. For example, if the forward voltage falls below a predefined threshold for a nominal constant driving current, the OLED may be considered to be defective, this detection is rather sensitive with respect to production tolerances (resp. OLED “binning”) and the corresponding OLED (forward) voltage variants resulting therefrom.

EP-2536257 discloses an organic electroluminescent illuminating apparatus which can detect a short-circuit when the short-circuit is generated in an area between the anode and the cathode. The apparatus includes an OLED, a drive circuit for driving the OLED, a temperature detection monitor for detecting the temperature of the OLED (particularly the temperature of the OLEDs front surface), and a monitor detection signal feedback circuit for providing a signal to the drive circuit on the basis of a signal from the temperature detection monitor. When a short-circuit occurs in a portion between anode and cathode of the OLED, its temperature will drastically rise and the temperature detection monitor will send an illuminance decrease signal to the monitor detection signal feedback circuit when it detects a temperature of a predetermined value or higher.

### SUMMARY OF THE INVENTION

It is an object of the present invention to provide an OLED device comprising an OLED and a short detection circuit for detecting a short in the OLED, wherein the short detection can be less sensitive with respect to production tolerances and the like. It is a further object of the present invention to provide a corresponding short detection circuit and a corresponding short detection method for detecting a short in an OLED. It is yet a further object of the present invention to provide a corresponding lighting system comprising the OLED device.

In a first aspect of the present invention, an OLED device is presented, wherein the OLED device comprises:

OLED, and

a short detection circuit for detecting a short in the OLED, wherein the short detection circuit comprises;

a temperature sensing unit for sensing is first and a second temperature of the OLED, the temperature sensing unit comprising a first temperature sensor being thermally coupled to the OLED at a first location thereof, and a second temperature sensor being, thermally coupled to the OLED at a second location thereof, the second location being different from the first location, wherein the first temperature sensor is adapted to sense the first temperature at the first location and the second temperature sensor is adapted to sense the second temperature at the second location, and

a short detection unit for detecting the short based on a difference between the first and the second temperature, the short detection unit being adapted to detect the short if the difference between the first and the second temperature is changed more than a predefined value compared to an operation of the OLED in a thermal steady state without a short.

Since the OLED device comprises a short detection circuit for detecting a short in the OLED, wherein the short detection circuit comprises (i) a temperature sensing unit for sensing a first and a second temperature of the OLED and (ii) a short detection unit for detecting the short based on a difference between the first and the second temperature, changes in the distribution of the temperature of the OLED, which result from the occurrence of the short, can be used for detecting the short. Such a short detection, which makes use of sensed temperatures of the OLED, can be less sensitive with respect to production tolerances resp. OLED binning.

As is understood by a person skilled in the art, the term “short” indicates a condition in which the OLED has an abnormally low impedance at a certain location. Such a short may occur during operation due to, e.g., defects caused by contaminations of the OLED substrate and/or layers resulting from an imperfect cleaning and handling production. The short may result in a significant increase in the temperature at the location of the defect (known also as “hot spot” effect).

By basing the detection of the short on a difference between a first and a second temperature, which are sensed by a first temperature sensor at a first location of the OLED and by a second temperature sensor at a second location of the OLED, a difference in the temperature of the OLED at the first and the second location, which is characteristic for the occurrence of the short, can he used for detecting the short. By doing so, it can be possible to make the detection of the short even more robust against changes in the ambient temperature.

In this embodiment, it is preferred that the short detection unit is adapted to detect the short if the difference between the first and the second temperature is changed more than a predefined value compared to an operation of the OLED in a thermal steady state without a short.

The heuristic, here, is that if the difference between the first and the second temperature is changed more than a predefined value compared to an operation of the OLED in a thermal steady state without a short, the difference in the temperature of the OLED at the first and the second location may he attributed to the occurrence of the short in the OLED.

The predefined value may be, e.g., an absolute value, such as X° C., wherein X is a suitably chosen threshold value, or a relative value, such as Y% more (or less) than during operation of the OLED in a thermal steady state without a short, wherein Y is a suitably chosen threshold value the predefined value can be characteristic for the OLED and may be set, e.g., during production of the OLED device. Alternatively, the predefined value may also be determined during operation of the OLED, e.g., by detecting the completion of the process of self-heating and by then determining, by making use of the first and the second temperature sensor, how the temperature of the OLED differs between the first location and the second location during the subsequent thermal steady state without a short. The predefined value may then suitably be set based on the determined difference.

Preferentially, the first and the second temperature sensor are adapted to repeatedly sense the temperatures of the OLED at the first and the second location. For example, the first and the second temperature sensor can be adapted to sense the temperature of the OLED at the first and the second location at periodic points in time, such as once per minute or the like.

It is further preferred that the first and second location are located such that a difference between a temperature of the OLED at the first location and a temperature of the OLED at the second location is larger than a predefined value during operation of the OLED in a thermal steady state without a short.

As will be explained in more detail below, also during operation of the OLED in a thermal steady state without a short, the distribution of the temperature of the OLED is usually not completely homogeneous. Rather, the temperatures at different locations of the OLED can be noticeably different, e.g., by a few ° C. It has been found by the present inventor that when the short occurs in the OLED, such differences can actually become reduced, depending on the location of the short. In order to be able to detect the short based on such a temperature reduction, it is therefore advantageous if the first and second location are located such that a difference between a temperature of the OLED at the first location and a temperature of the OLED at the second location is larger than a predefined value during operation of the OLED in a thermal steady state without a short.

It is preferred that the temperature sensing unit further comprises a third temperature sensor being thermally coupled to the OLED at a third location thereof, the third location being different from the first and the second location, wherein the third temperature sensor is adapted to sense a third temperature of the OLED at the third location, wherein the short detection unit is adapted to detect the short if at least one of the difference between the first and the second temperature and a difference: between the first and the third temperature is changed more than a predefined value compared to an operation of the OLED in a thermal steady state without a short.

Making use of more than two temperature sensors can be advantageous, in particular, for large OLEDs, in order to be able to safely detect shorts occurring in different parts of the OLED.

Alternatively to what is described above, the OLED device may have a construction wherein the temperature sensing unit comprises a first temperature sensor being thermally coupled to the OLED at a first location thereof, wherein the first temperature sensor is adapted to sense the first temperature at a first point in time and the second temperature and a second point in time, the second point in time being different from the first point in time.

By basing the detection of the short on a difference between a first and a second temperature, which are sensed by a first temperature sensor at a first location of the OLED at two different points in time, a temporal change in the temperature of the OLED at the first location, which is characteristic for the occurrence of the short, can be used for detecting the short. By doing so, it can be possible to detect the short using only a single temperature sensor.

In this alternative construction, it is preferred that the short detection unit is adapted to detect the short if a time-temperature gradient corresponding to the difference between the first temperature and the second temperature is changed more than a predefined value compared to an operation of the OLED in a thermal steady state without a short.

Here and in the following, the phrase “thermal steady state without a short” refers to a pristine state of the OLED, in which a process of self-heating, which occurs after the OLED has been turned on, has already been completed, such that the temperatures at different locations of the OLED are substantially steady over time unless they are (slowly) changed due to changes in the ambient temperature.

The heuristic, here, is that if a time-temperature gradient corresponding to the difference between the first temperature and the second temperature is changed more than a predefined value compared to an operation of the OLED in a thermal steady state without a short, the temporal change in the temperature of the OLED at the first location may be attributed to the occurrence of the short in the OLED.

The time-temperature gradient may be determined. e.g., by simply calculating a ratio of the difference between the first and the second temperature (temperature difference) and the time difference between the first point in time and the second point in time (time difference in which the temperature difference occurred).

The predefined value may be, e.g., an absolute value, such as X° C. per second, wherein X is a suitably chosen threshold value, or a relative value, such as Y% per second more than during operation of the OLED in a thermal steady state without a short, wherein Y is a suitably chosen threshold value. The predefined value can be characteristic for the OLED and may be set, e.g., during production of the OLED device. Alternatively, the predefined value may also be determined during operation of the OLED, e.g., by detecting the completion of the process of self-heating and by then determining, by making use of the first temperature sensor, how the temperature of the OLED temporally changes at the first location during the subsequent thermal steady state without a short. The predefined value may then suitably be set based on the determined temporal temperature changes.

Preferentially, the first temperature sensor is adapted to repeatedly sense the temperature of the OLED at the first location. For example, the first temperature sensor can be adapted to sense the temperature of the OLED at the first location at periodic points in time, such as once per minute or the like, wherein each pair of adjacent points in time constitutes the first point in time and the second point in time.

It shall be noted that it may not be actually necessary to explicitly calculate the time-temperature gradient corresponding to the difference between the first temperature and the second temperature in order to detect the short. For example, it may be possible to directly compare the difference between the first and the second temperature with the predefined value if the predefined value relates to a time difference during the thermal steady state without a short that is equal to the time difference between the first point in time and the second point in time.

It shall further be noted that usually, the time constant with which the temperature of the OLED at the first location will change as a result of the occurrence of the short will be much shorter than the time constant(s) with which the distribution of the temperature of the OLED changes due to changes in the ambient temperature. The time difference between the first point in time and the second point in time can therefore preferably be set such the detection of the short is substantially not influenced by changes in the ambient temperature.

It is further preferred that the temperature sensing unit further comprises a second temperature sensor being thermally coupled to the OLED at a second location thereof, the second location being different from the first location, wherein the second temperature sensor is adapted to sense a third temperature of the OLED at a third point in time and a fourth temperature of the OLED and a fourth point in time, the fourth point in time being different from the third point in time, wherein the short detection unit is adapted to detect the short if at least one of a time-temperature gradient corresponding to the difference between the first temperature and the second temperature and a time-temperature gradient corresponding to a difference between the third temperature and the fourth temperature is changed more than a predefined value compared to an operation of the OLED in a thermal steady state without a short.

Making use of more than one temperature sensor can be advantageous, in particular, for large OLEDs, in order to be able to safely detect shorts occurring in different parts of the OLED.

Preferentially, the second temperature sensor is adapted to repeatedly sense the temperature of the OLED at the second location. For example, the second temperature sensor can be adapted to sense the temperature of the OLED at the second location at periodic points in time, such as once per minute or the like, wherein each pair of adjacent points in time constitutes the third point in time and the fourth point in time. In particular, the respective first point(s) in time can be equal to the respective third point(s) in time and the respective second point(s) in time can be equal to the respective fourth point(s) in time.

For all constructions described above, if the OLED comprises a substrate, a light-emitting layer, and an encapsulation encapsulating the light-emitting, layer on the substrate, wherein the encapsulation comprises a cover lid attached to the substrate, it is preferred that the first location is not located on the cover lid.

Since the cover lid is typically attached to the substrate such that an internal cavity providing a relatively high thermal isolating effect results within the encapsulation, it can be better if the first location, i.e., the location at which the first temperature sensor is thermally coupled to the OLED, is not located on the cover lid, but is located e.g. next to it. Alternatively, if the OLED comprises a substrate, a light-emitting layer, and an encapsulation encapsulating the light-emitting layer on the substrate, wherein the encapsulation is a thin-film encapsulation, it is preferred that the first location is located on the thin-film encapsulation.

Since the thin-film encapsulation typically has only a very small thickness and is normally in direct contact with the further layers of the OLED, it can provide a relatively good thermal transfer, which allows the first temperature sensor to be thermally coupled to the OLED at a first location located on the thin-film encapsulation, e.g., centered with respect to the light-emitting layer.

It is preferred that the short detection circuit further comprises an ambient temperature sensing unit for sensing the ambient temperature of the OLED, wherein the short detection unit is adapted to account for changes in the ambient temperature when detecting the short.

As already noted above, usually, the time constant with which the temperatures of the OLED at the first location (as well as other locations of the OLED) will change as a result of the occurrence of the short will be much shorter than the time constant(s) with which the distribution of the temperature of the OLED changes due to changes in the ambient temperature. Nonetheless, by sensing the ambient temperature of the OLED and by accounting for changes in the ambient temperature when detecting the short, e.g., by suitably adjusting the predefined value(s) in accordance with the ambient temperature, it can be possible to make the detection of the short even more robust against changes in the ambient temperature.

It is further preferred that the short detection circuit further comprises a short protection unit for being connected to a current source for providing a driving current to the OLED, wherein the short protection unit is adapted to switch of or reduce the driving current provided to the OLED in case the short is detected.

By switching off or reducing the driving current provided to the OLED in case the short is detected, the risk of providing a danger for a human being due to the high local temperature at the location of the short (i.e., due to the “hot spot” effect), which can easily reach values well above 100 degrees Celsius, can be reduced.

In a second aspect of the present invention, a lighting system is presented, wherein the lighting system comprises:

an OLED device according to the first aspect, and

a current source for providing a driving current to the OLED.

In a third aspect of the present invention, a short detection circuit for detecting a short in an OLED is presented, wherein the short detection circuit comprises:

a temperature sensing unit for sensing a first and a second temperature of the OLED, the temperature sensing unit comprising a first temperature sensor being thermally coupled to the OLED at a first location thereof, and a second temperature sensor being thermally coupled to the OLED at a second location thereof, the second location being different from the first location, wherein the first temperature sensor is adapted to sense the first temperature at the first location and the second temperature sensor is adapted to sense the second temperature at the second location, and

a short detection unit for detecting the short based on a difference between the first and the second temperature, the short detection unit being adapted to detect the short if the difference between the first and the second temperature is changed more than a predefined value compared to an operation of the OLED in a thermal steady state without a short.

In a fourth aspect of the present invention, a short detection method for detecting a short in an OLED is presented, wherein the short detection method comprises:

sensing with a temperature sensing unit a first temperature at a first location of the OLED and a second temperature at a second location of the OLED, the second location being different from the first location, and

detecting with a short detection unit the short if the difference between the first and the second temperature is changed more than a predefined value compared to an operation of the OLED in a thermal steady state without as short.

It shall be understood that the OLED device of the first aspect, the lighting system of the second aspect, the short detection circuit of the third aspect, and the short detection method of the fourth aspect have similar and/or identical preferred embodiments, in particular, as defined in the dependent claims.

It shall be understood that a preferred embodiment of the present invention can also be any combination of the dependent claims or above embodiments with the respective independent claim.

These and other aspects of the invention will be apparent from and elucidated with reference to the embodiments described hereinafter.

### BRIEF DESCRIPTION OF THE DRAWINGS

In the following drawings:

FIG. 1 illustrates results from an experiment performed in order to assess the effects of a short occurring in an OLED during operation.

FIG. 2 shows a graph exemplarily illustrating the temperatures sensed by the three temperature sensors at the locations of the OLED shown in FIG. 1.

FIG. 3 shows schematically and exemplarily a first embodiment of a lighting system.

FIG. 4 shows graphs illustrating temperatures sensed in experiments at different locations of exemplary OLEDs before and after the occurrence of a short in the OLEDs.

FIG. 5 shows schematically and exemplarily a second embodiment of a lighting system.

FIG. 6 shows graphs illustrating temperatures sensed in experiments at different locations of exemplary OLEDs before and after the occurrence of a short in the OLEDs.

FIG. 7 shows schematically and exemplarily a first example of a location at which a temperature sensor may be thermally coupled to an OLED.

FIG. 8 shows schematically and exemplarily a second example of as location at which a temperature sensor may be thermally coupled to an OLED.

FIG. 9 shows schematically and exemplarily further examples of configurations of locations at which temperature sensors may be thermally coupled to an OLED.

FIG. 10 shows a flowchart exemplarily illustrating a first embodiment of a short detection method for detecting a short in an OLED, and

FIG. 11 shows a flowchart exemplarily illustrating a second embodiment of a short detection method for detecting a short in an OLED.

### DETAILED DESCRIPTION OF EMBODIMENTS

In the drawings, like or corresponding reference numerals refer to like or corresponding parts and/or elements.

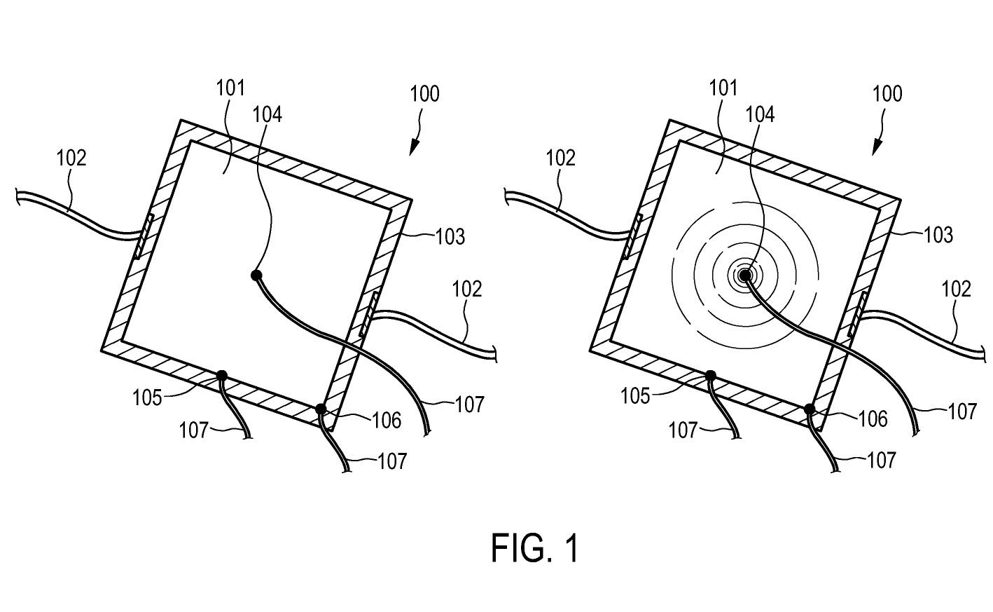

FIG. 1 illustrates results from an experiment performed in order to assess the effects resulting from a short occurring in an OLED 100 during operation. The OLED 100 comprises a substrate, here, a glass substrate, on which several layers are deposited. These layers include: a transparent electrode layer, here, an indium tin oxide (ITO) layer, which functions as an anode, a light-emitting layer, here, formed from a number of functional layers for achieving the recombination of holes and electrons to emit the desired spectrum of light, a reflective electrode layer, which functions as a cathode, and a thin-film encapsulation encapsulating the light-emitting layer on the substrate (all not shown in detail in the figure). By means of this layered structure, a light-emitting area 101 is realized, which, in this example, is 5×5 cm² in size. In this experiment, the OLED 100 is electrically contacted via cables 102 in a contacting area 103 surrounding the light-emitting area 101.

The view on the left side of FIG. 1 shows the state of the OLED 100 right after it has been turned on, i.e., when the OLED 100 is provided via the cables 102 with a driving current, in this experiment, a constant driving current of 300 mA, from a current source (not shown in the figure). As illustrated in the figure, in this state, the distribution of the luminance is substantially homogeneous across the light-emitting area 101.

Once the OLED 100 is provided with the constant driving current from the current source, the OLED 100 begins to emit light from the light-emitting area 101 and a process of self-heating occurs. The OLED 100 reaches a thermal steady state after a couple of minutes, here, after about 7 minutes, of operation. In this example, a short occurs at the center of the light-emitting area 101 after about 10:30 minutes of operation (view on the right side of FIG. 1). While the current source still provides the OLED 100 with the constant driving current of 300 mA, the local current density in the light-emitting area 101 increases significantly near the short and two effects can be observed:
a) Due to a lateral voltage drop across the electrode layers, the distribution of the density of the driving current, and, in response, the distribution of the luminance across the light-emitting area 101 becomes very inhomogeneous.
b) The distribution of the temperature of the OLED 100 also changes significantly compared to the state before the occurrence of the short. In particular, a high temperature peak occurs at the location of the short. (In this experiment, the temperature has been sensed by three temperature sensors 104, 105, and 106 being attached to the light-emitting side of the substrate of the OLED 100 at the center of the light-emitting area 101, at a border of the light-emitting area 101, and at a corner of the light-emitting area 101, respectively. The reference numeral 107 denotes cables used in the experiment for conveying the signals representing the temperatures sensed by the temperature sensors 104, 105, and 106.)

It has been found by the present inventor that the change of the distribution of the temperature of the OLED 100 can be detected even at the border and the corners of the light-emitting area 101, despite the large distance, here, 2.5 cm and about 3.5 cm, respectively, between the location of the short at the center of the light-emitting area 101 and the locations of the OLED 100 at which the temperatures are sensed by the temperature sensors 105 and 106.

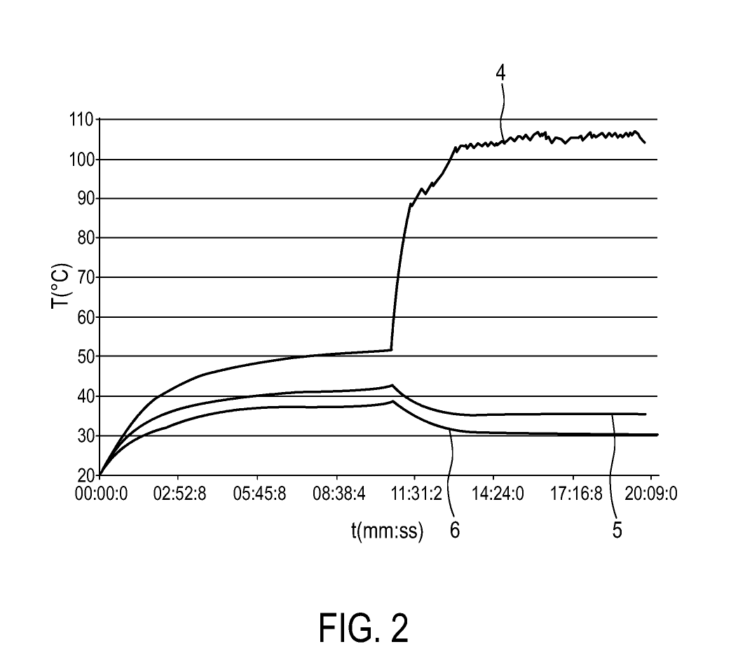

The temperatures sensed by the three temperature sensors 104, 105, and 106 at the locations of the OLED 100 shown in FIG. 1 are exemplarily illustrated by the graph shown in FIG. 2. As can be seen, after the OLED 100 has been turned on, the temperature T of the OLED 100 rises due to the self-beating process occurring under normal operation. As already mentioned above, the temperature stabilizes after about 7 minutes of operation. The temperatures in this thermal steady state are about 50° C, at the center of the light-emitting area 101 (curve 4, sensed by temperature sensor 104), about 42° C. at the border of the light-emitting area 101 (curve 5, sensed by temperature sensor 105), and about 38° C. at the corner of the light-emitting area 101 (curve 6, sensed by temperature Sensor 106), respectively. As further already mentioned above, after about 10:30 minutes of operation, a short occurs at the center of the light-emitting area 101. The current source still provides the OLED 100 with the constant driving current of 300 mA, but due to the short, the distribution of the temperature of the OLED 100 changes significantly compared to the thermal steady state before the occurrence of the short. As can be seen from FIG. 2 after about 5 more minutes of operation, the temperatures reach a new thermal steady state, in which they are about 105° C. at the center of the light-emitting area 101 (again, curve 4, sensed by temperature sensor 104), about 35° C. at the border of the light-emitting area 401 (again, curve 5, sensed by temperature sensor 105), and about 30° C. at the corner of the light-emitting area 101 (again, curve 6, sensed by temperature sensor 106), respectively. Compared to the first thermal steady state after about 7 minutes of operation, the temperatures are changed by about +65° C., about −7° C., and about −8° C., respectively.

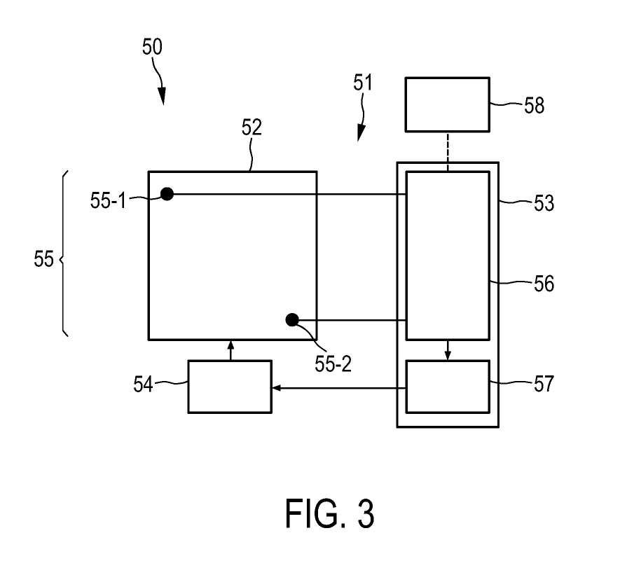

FIG. 3 shows schematically and exemplarily a first embodiment of a lighting system 50. The lighting system 50 comprises an OLED device 51, wherein the OLED device 51 comprises an OLED 52 and a short detection circuit 53 for detecting a short in the OLED 52. The lighting system 50 further comprises a current source 54 for providing a driving current, e.g., to constant driving current, to the OLED 52.

The short detection circuit 53 comprises a temperature sensing unit 55 for sensing a first and a second temperature of the OLED 52 and a short detection unit 56 for detecting a short in the OLED 52 based on as difference between the first and the second temperature. In particular, in this embodiment, the temperature sensing unit 55 comprises a first temperature sensor 55-1 being thermally coupled to the OLED 52 at a first location thereof, here, at the top-left corner of the OLED 52. The first temperature sensor 55-1 is adapted to sense the first temperature at a first point in time and the second temperature at a second point in time, the second point in time being different from the first point in time. The short detection unit 56, here, is adapted to detect the short if a time-temperature gradient corresponding to the difference between the first temperature and the second temperature is changed more than a predefined value compared to an operation of the OLED 52 in a thermal steady state without a short.

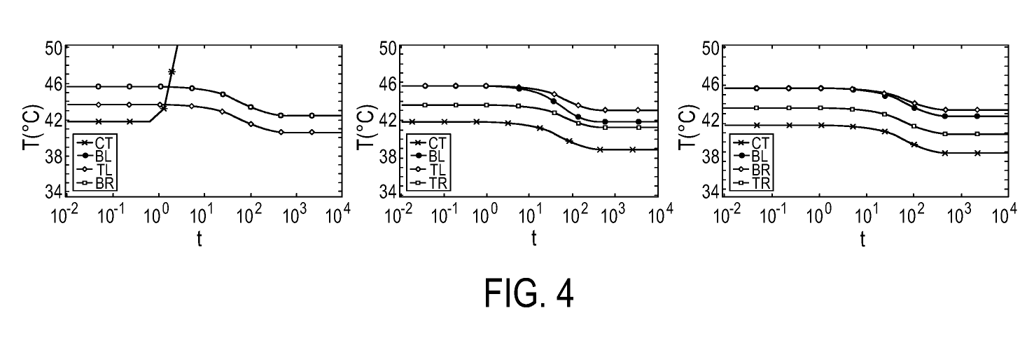

This will be explained in more detail with reference to FIG. 4, which shows graphs illustrating temperatures sensed in experiments at different locations of exemplary OLEDs before and after the occurrence of a (small) short in the OLEDs. In more detail, the graph on the left side of the figure illustrates the temperatures at the center (curve “CT”), the bottom-left corner (curve “BL”), the top-left corner (curve “TL”), and the bottom-right corner (curve “BR”) of an exemplary OLED before and after a short occurs at the center of the OLED at a point in time t=10⁰ seconds. Likewise, the graph in the middle of the figure illustrates the temperatures at the center (curve “CT”), the bottom-left corner (curve “BL”), the top-left corner (curve “TL”), and the top-right corner (curve “TR”) of an exemplary OLED before and after a short occurs at the left border of the OLED at a point in time t=10⁰ seconds. Finally, the graph on the right side of the figure illustrates the temperatures at the center (curve “CT”), the bottom-left corner (curve “BL”), the bottom-right corner (curve “BR”), and the top-right corner (curve “TR”) of an exemplary OLED before and after a short occurs at the top-left corner of the OLED at a point in time t=10⁰ seconds. In all three graphs, the time axis is given logarithmically, where values such as t=10 ⁻¹ relate to points in time before the occurrence of the short.

As can be seen, before a short occurs in the exemplary OLEDs, the OLEDs operate in a thermal steady state, i.e., the temperatures at the different locations of the OLEDs are substantially steady over time. When a short occurs at the center (graph on the left side of the figure) of the exemplary OLED, the temperature at the center (curve “CT”) of the OLED increases strongly, eventually resulting in as “hot spot” effect. In contrast, the temperatures at the bottom-left corner (curve “BL”), the top-left corner (curve “TL”), and the bottom-right corner (curve “BR”) of the OLED decrease due to the changes in the distribution of the temperature of the OLED resulting from the occurrence of the short. The described behaviour can also be found in a similar manner when a short occurs at the left border (graph in the middle of the figure) resp. at the top-left corner (graph on the right side of the figure) of the exemplary OLEDs. In these cases, the temperatures at the center (curve “CT”), the bottom-left corner (curve “BL”), the top-left corner (curve “TL”), and the top-right corner (curve “TR”) of the OLED resp. the temperatures at the center (curve “CT”), the bottom-left corner (curve “BL”), the bottom-right corner (curve “BR”), and the top-right corner (curve “TR”) of the OLED also decrease as a result of the occurrence of the short.

From the above, it can generally be understood that when a short occurs in an OLED, the time-temperature gradient at a given location of the OLED, such as at the top-left corner of the OLED 52 shown in FIG. 3, changes compared to an operation of the OLED in a thermal steady state without a short. By determining whether such change exceeds a predefined value, e.g., an absolute value, such as X° C., wherein X is a suitably chosen threshold value, the short can be detected in the OLED.

Returning to FIG. 3, while it may be possible to detect a short in the OLED 52 using only one temperature sensor 55-1, it can be advantageous, in particular, for large OLEDs, to make use of more than one temperature sensor in order to safely detect shorts occurring in different parts of the OLED. Therefore, in this embodiment, as shown in FIG. 3, the temperature sensing unit 55 further comprises a second temperature sensor 55-2 being thermally coupled to the OLED 52 at a second location thereof, here, at the bottom-right corner of the OLED 52. The second temperature sensor 55-2 is adapted to sense a third temperature of the OLED 52 at a third point in time and a fourth temperature of the OLED 52 at a fourth point in time, the fourth point in time being different from the third point in time. The short detection unit 56, here, is adapted to detect the short if at least one of a time-temperature gradient corresponding to the difference between the first temperature and the second temperature and a time-temperature gradient corresponding to a difference between the third temperature and the fourth temperature is changed more than a predefined value compared to an operation of the OLED 52 in a thermal steady state without a short.

The short detection circuit 53, in this embodiment, further comprises a short protection unit 57 being connected to the current source 54. The short protection unit 57 is adapted to switch off the driving current provided to the OLED 52 if the short is detected. Therewith, the risk of providing a danger for a human being due to the high local temperature at the location of the short (i.e., due to the “hot spot” effect), which can easily reach values well above 100 degrees Celsius, can be reduced.

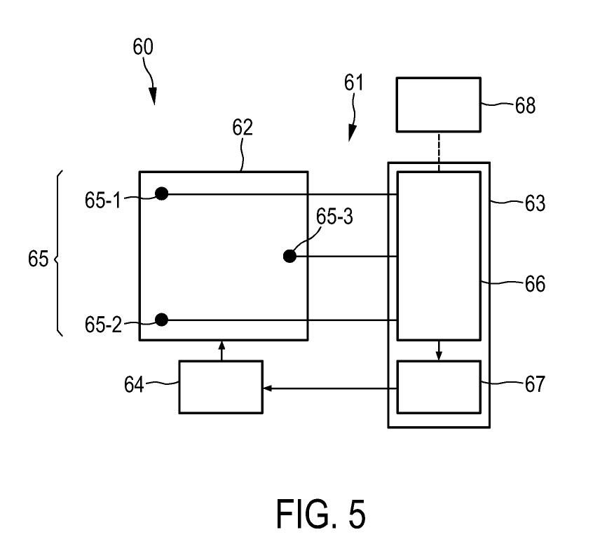

FIG. 5 shows schematically and exemplarily a second embodiment of a lighting system 60. The lighting system 60 comprises an OLED device 61, wherein the OLED device 61 comprises an OLED 62 and a short detection circuit 63 for detecting a short in the OLED 62. The lighting system 60 further comprises a current source 64 for providing a driving current, e.g., a constant driving current, to the OLED 62.

The short detection circuit 63 comprises a temperature sensing unit 65 for sensing a first and a second temperature of the OLED 62 and a short detection unit 66 for detecting a short in the OLED 62 based on a difference between the first and the second temperature. In particular, in this embodiment, the temperature sensing unit 65 comprises a first and a second temperature sensor 65-1, 65-2 being thermally coupled to the OLED 62 at a first and a second location thereof, here, at the top-left corner of the OLED 62 and at the bottom-left corner of the OLED 62. The first temperature sensor 65-1 is adapted to sense the first temperature at the first location and the second temperature sensor 65-2 is adapted to sense the second temperature at the second location.

The short detection unit 66, here, is adapted to detect the short if the difference between the first and the second temperature is changed more than a predefined value compared to an operation of the OLED 62 in a thermal steady state without a short.

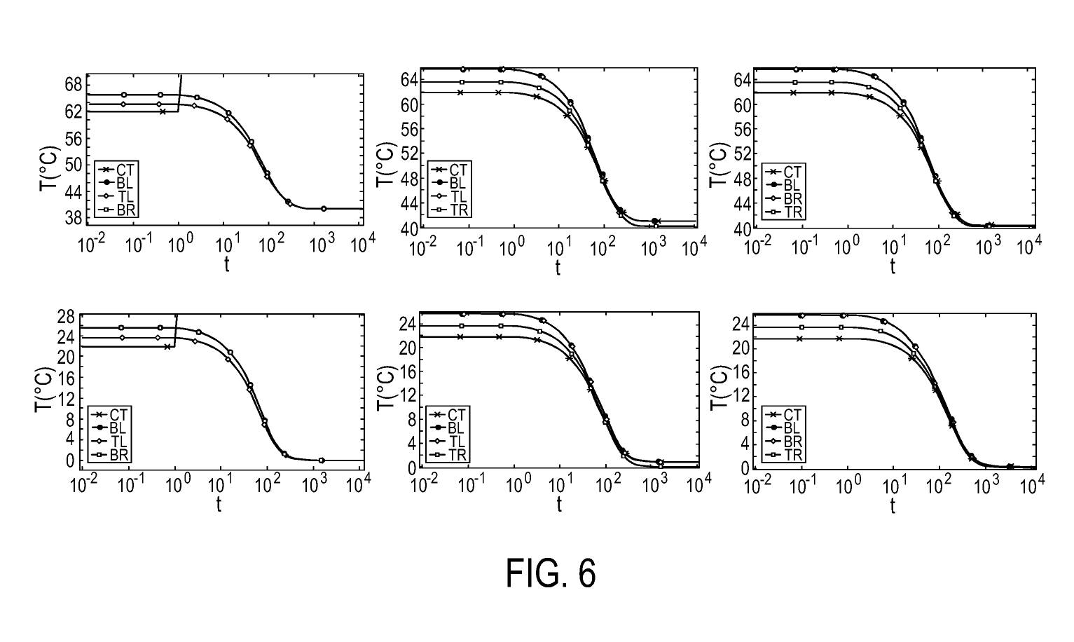

This will be explained in more detail with reference to FIG. 6, which shows graphs illustrating temperatures sensed in experiments at different locations of exemplary OLEDs before and after the occurrence of a (large) short in the OLEDs. In more detail, the graphs on the left side of the figure illustrate the temperatures at locations at the center (curve “CT”), the bottom-left corner (curve “BL,”), the top-left corner (curve “TL”), and the bottom-right corner (curve “BR”) of exemplary OLEDs before and after a short occurs at the center of the OLEDs at a point in time t=10⁰ seconds for an ambient temperature of 40° C. (top graph) and an ambient temperature of 0° C. (bottom graph). Likewise, the graphs in the middle of the figure illustrate the temperatures at locations at the center (curve “CT”), the bottom-left corner (curve “BL”), the top-left corner (curve “TL”), and the top-right corner (curve “TR”) of an exemplary OLED before and after a short occurs at the left border of the OLED at a point in time t=10⁰ seconds for an ambient temperature of 40° C., (top graph) and an ambient temperature of 0° C. (bottom graph). Finally, the graphs on the right side of the figure illustrate the temperatures at locations at the center (curve “CT”), the bottom-left corner (curve “BL”), the bottom-right corner (curve “BR”), and the top-right corner (curve “TR”) of an exemplary OLED before and after a short occurs at the top-left corner of the OLED at a point in time t=10⁰ seconds for an ambient temperature of 40° C. (top graph) and an ambient temperature of 0° C. (bottom graph). In all six graphs, the time axis is given logarithmically, where values such as t=10⁻¹ relate to points in time before the occurrence of the short.

As can be seen, before a short occurs in the exemplary OLEDs, the OLEDs operate in a thermal steady state, i.e., the temperatures at the different locations of the OLEDs are substantially steady over time. Moreover, the temperatures at different locations of the OLED are—at least in part—noticeably different, e.g., in the top graph on the left side of the figure, the curve “TL” and the curve “BR” differ by more than 2° C. When a short occurs at the center (graphs on the left side of the figure) of the exemplary OLEDs, the temperature at the center (curve “CT”) of the OLED increases strongly, eventually resulting in a “'hot spot” effect. In contrast, the temperatures at the bottom-left corner (curve “BL”), the top-left corner (curve “TL”), and the bottom-right corner (curve “BR”) of the OLED decrease due to the changes in the distribution of the temperature of the OLED resulting from the occurrence of the short. In particular, it can be seen that the differences between the later temperatures become reduced, whereas their difference to the temperature at the center (curve “CT”) becomes increased.

The described behaviour can also be found in a similar manner when a short occurs at the left border (graphs in the middle of the figure) resp. at the top-left corner (graphs on the right side of the figure) of the exemplary OLEDs. In these cases, the temperatures at the center (curve “CT”), the bottom-left corner (curve “BL”), the top-left corner (curve “TL”), and the top-right corner (curve “TR”) of the OLEDs resp. the temperatures at the center (curve “CT”), the bottom-left corner (curve “BL”), the bottom-right corner (curve “BR”), and the top-right corner (curve “TR”) of the OLEDs also decrease as a result of the occurrence of the short and their differences become reduced.

From the above, it can generally be understood that when a short occurs in an OLED, the difference between the temperatures at two different locations of the OLED, such as at the top-left corner and the bottom-left corner of the OLED 62 shown in FIG. 3, may change compared to an operation of the OLED in a thermal steady state without a short. By determining whether such change exceeds a predefined value, e.g., an absolute value, such as X° C., wherein X is a suitably chosen threshold value, the short can be detected in the OLED.

Returning to FIG. 5, in this embodiment, the first and second location are located such that a difference between a temperature of the OLED 62 at the first location and a temperature of the OLED 62 at the second location is larger than a predefined value during operation of the OLED 62 in a thermal steady state without a short. This allows detecting the short based on a reduction of the difference between the first and the second temperature, as exemplarily described with reference to FIG. 6 above.

While it may be possible to detect a short in the OLED 62 using only two temperature sensors 65-1, 65-2, it can be advantageous, in particular, for large OLEDs, to make use of more than two temperature sensors in order to safely detect shorts occurring in different parts of the OLED. Therefore, in this embodiment, the temperature sensing unit 65 further comprises a third temperature sensor 65-3 being thermally coupled to the OLED 62 at a third location thereof here, at the right border of the OLED 62. The third temperature sensor 65-3 is adapted to sense a third temperature of the OLED 62 at the third location. The short detection unit 66, here, is adapted to detect the short if at least one of the difference between the first and the second temperature and a difference between the first and the third temperature is changed more than a predefined value compared to an operation of the OLED 61 in a thermal steady state without a short.

The short detection circuit 63, in this embodiment, further comprises a short protection unit 67 being connected to the current source 64. The short protection unit 67 is adapted to switch off the driving current provided to the OLED 62 if the short is detected. Therewith, the risk of providing a danger for a human being due to the high local temperature at the location of the short (i.e., due to the “hot spot” effect), which can easily reach values well above 100 degrees Celsius, can be reduced.

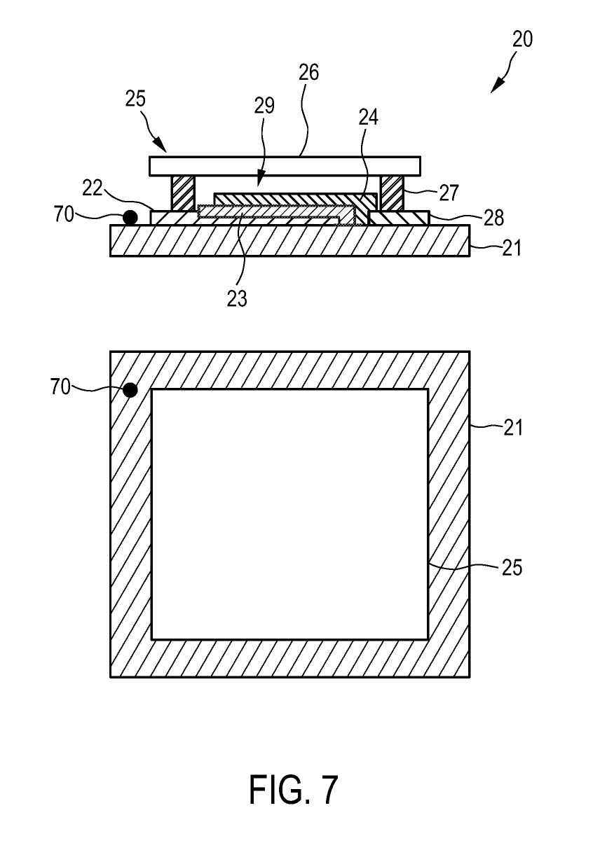

FIG. 7 shows schematically and exemplarily a first example of a location at which a temperature sensor 70 can be thermally coupled to an OLED 20. As can be seen from the sectional drawing at the top of the figure, the OLED 20 comprises a substrate 21, here, a glass substrate, on which several layers are deposited. These layers include: a transparent electrode layer 22, here, an indium tin oxide (ITO) layer, which functions as an anode, a light-emitting layer 23, here, formed from a number of functional layers (not shown in the figure) for achieving the recombination of holes and electrons to emit the desired spectrum of light, a reflective electrode layer 24, which functions as a cathode, and an encapsulation 25 encapsulating the light-emitting layer 23 on the substrate 21. In order to able to electrically contact the transparent electrode layer 22 (i.e., the anode), this layer extends to the outside of the encapsulation 25. Moreover, in order to be able to electrically contact the reflective electrode layer 24 (i.e., the cathode), this layer is in contact with a contact element 28 that also extends to the outside of the encapsulation 25. The encapsulation 25, here, comprises a cover lid 26 attached to the substrate 21, in this case, by a glue 27.

Since the cover lid 26 is typically attached to the substrate 21 such that an internal cavity 29 providing a relatively high thermal isolating effect results within the encapsulation 25, it can be better if the location at which the temperature sensor 70 is thermally coupled to the OLED 20 is not located on the cover lid 26, but is located e.g. next to it (cf. also the plan view drawing at the bottom of the figure).

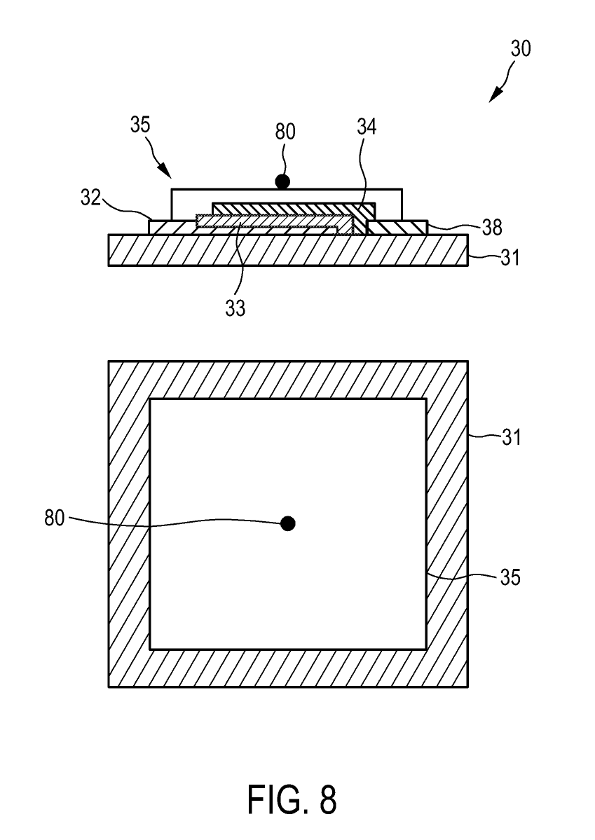

FIG. 8 shows schematically and exemplarily a second example of as location at which a temperature sensor 80 can be thermally coupled to an OLED 30. As can be seen from the sectional drawing at the top of the figure, the OLED 30 comprises a substrate 31, here, a glass substrate, on which several layers are deposited. These layers include: a transparent electrode layer 32, here, an indium tin oxide (ITO) layer, which functions as an anode, a light-emitting layer 33, here, formed from a number of functional layers (not shown in the figure) for achieving the recombination of holes and electrons to emit the desired spectrum of light, a reflective electrode layer 34, which functions as a cathode, and an encapsulation 35 encapsulating the light-emitting layer 33 on the substrate 31. In order to able to electrically contact the transparent electrode layer 32 (i.e., the anode), this layer extends to the outside of the encapsulation 35. Moreover, in order to be able to electrically contact the reflective electrode layer 34 (i.e., the cathode), this layer is in contact with a contact element 38 that also extends to the outside of the encapsulation 35. The encapsulation 35, here, is a thin-film encapsulation.

Since the thin-film encapsulation 35 typically has only a very small thickness and is normally in direct contact with the further layers of the OLED 30, it can provide a relatively good thermal transfer, which allows the temperature sensor 80 to be coupled at a location located on the thin-film encapsulation 35, e.g., centered with respect to the light-emitting layer 33 (cf. also the plan view drawing at the bottom of the figure).

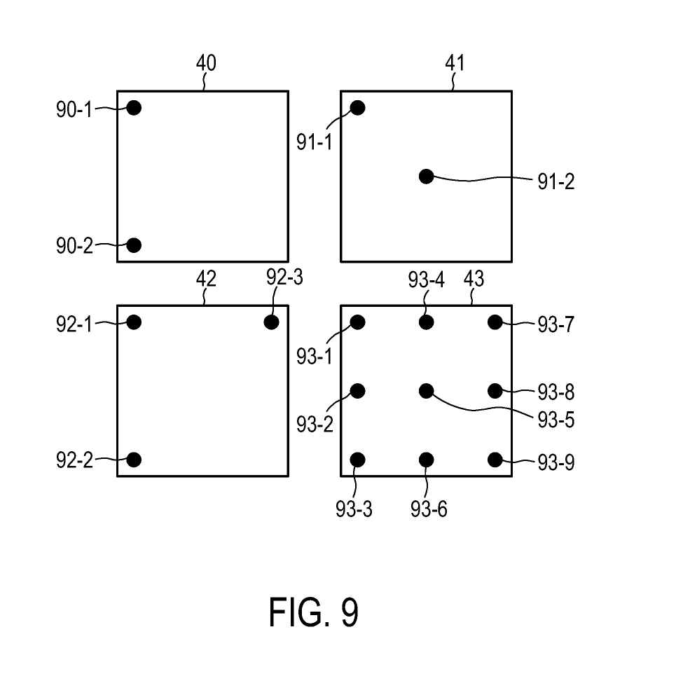

FIG. 9 shows schematically and exemplarily further examples of configurations of locations at which temperature sensors 90-1 . . . 93-9 can be thermally coupled to an OLED 40, 41, 42, 43.

On the top-left of the figure, a configuration is shown, in which two temperature sensors 90-1, 90-2 are thermally coupled to an OLED 40 at two different locations thereof, in this example, at two different corners of the OLED 40. On the top-right of the figure, a configuration is shown, in which two temperature sensors 91-1, 91-2 are thermally coupled to an OLED 41 at two different locations thereof, in this example, at a corner and at the center of the OLED 41. On the bottom-left of the figure, as configuration is shown, in which three temperature sensors 92-1, 92-2, 92-3 are thermally coupled to an OLED 42 at three different locations thereof, in this example, at three different corners of the OLED 42. On the bottom-right of the figure, a configuration is shown, in which nine temperature sensors 91-1, 93-2, 93-3, 93-4, 93-5, 93-6, 93-7, 93-8, 93-9 are thermally coupled to an OLED 43 at nine different locations thereof, in this example, in a square grid covering the OLED 43. In general, the accuracy of the short detection may be increased by increasing the number and density of the temperature sensors thermally coupled to an OLED.

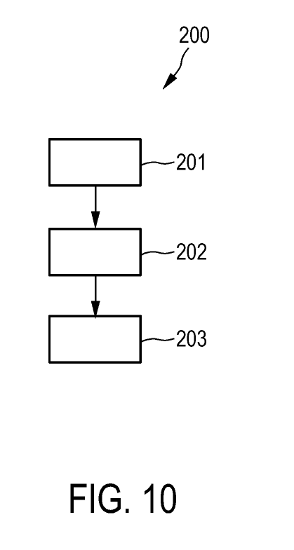

In the following, a first embodiment of a short detection method 200 for detecting a short in an OLED 52 will exemplarily be described with reference to a flowchart shown in FIG. 10. The short detection method 200 can be used, e.g., in the OLED device 51 shown in FIG. 3, where it can be performed by the short detection circuit 53.

The short detection method 200 senses a first and a second temperature of the OLED 52, by a temperature sensing unit 55. In this embodiment, the temperature sensing unit 55 comprises a first temperature sensor 55-1 being thermally coupled to the OLED 52 at a first location thereof. In step 201, the first temperature is sensed at a first point in time, by the first temperature sensor 55-1, and, in step 202, the second temperature is sensed at a second point in time, the second point in time being different from the first point in time, by the first temperature sensor 55-1. In step 203, the short is detected based on a difference between the first and the second temperature, by a short detection unit 56.

Here, the short is detected if a time-temperature gradient corresponding to the difference between the first temperature and the second temperature is changed more than a predefined value compared to an operation of the OLED 52 in a thermal steady state without a short. For more details in this regard, reference is made to the corresponding description of the OLED device 51 shown in FIG. 3.

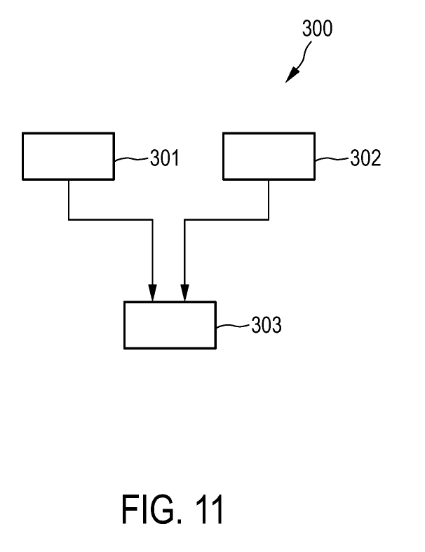

In the following, a second embodiment of a short detection method 300 for detecting a short in an OLED 62 will exemplarily be described with reference to a flowchart shown in FIG. 11. The short detection method 300 can be used, in the OLED device 61 shown in FIG. 5, where it can be performed by the short detection circuit 63.

The short detection method 300 senses a first and a second temperature of the OLED 62, by a temperature sensing unit 65. In this embodiment, the temperature sensing unit 65 comprises a first and a second temperature sensor 65-1, 65-2 being thermally coupled to the OLED 62 at a first and a second location thereof, the second location being different from the first location, in step 301, the first temperature is sensed at the first location, by the first temperature sensor 65-1, and, in step 302, the second temperature is sensed at the second location, by the second temperature sensor 65-2. In step 303, the short is detected based on a difference between the first and the second temperature, by a short detection unit 66.

Here, the short is detected if the difference between the first and the second temperature is changed more than a predefined value compared to an operation of the OLED 62 in a thermal steady state without a short. For more details in this regard, reference is made to the corresponding description of the OLED device 61 shown in FIG. 5.

While in both the embodiments of a lighting system 50, 60 shown in FIGS. 3 and 5 above, the short protection unit 56, 66 is adapted to switch off the driving current provided to the OLED 52, 62 in case a short is detected, in other embodiments, the short protection unit 56, 66 can also be adapted to merely reduce the driving current provided to the OLED 52, 62 in case a short is detected.

In both the embodiments of a lighting system 50, 60 shown in FIGS. 3 and 5, the short detection circuit 53, 63 can further comprise an ambient temperature sensing unit 58, 68 for sensing the ambient temperature of the OLED 52, 62. The short detection unit 56, 66 can then be adapted to account for changes in the ambient temperature when detecting the short.

The temperature sensor(s) should normally be small with respect to the OLED to which it is/they are thermally coupled. For example, for an OLED size of 5×5 cm², the size of the temperature sensor(s) should preferably be in the range of a several min². Suitable temperature sensor(s) include small-sized thermocouples and/or commonly used NTCs (Negative Temperature Coefficient).

Other variations to the disclosed embodiments can be understood and effected by those skilled in the art in practicing the claimed invention, from a study of the drawings, the disclosure, and the appended claims.

In the claims, the word “comprising” does not exclude other elements or steps, and the indefinite article “a” or “an” does not exclude a plurality.

A single unit or device may fulfill the functions of several items recited in the claims. For example, while in both the embodiments of a lighting system 50, 60 shown in FIGS. 3 and 5 above, the short detection unit 56, 66 and the short protection unit 57, 67 are shown as two separate units, they may also be realized as a single unit. The mere fact that certain measures are recited in mutually different dependent claims does not indicate that a combination of these measures cannot be used to advantage.

A computer program may be stored/distributed on a suitable medium, such as an optical storage medium or a solid-state medium, supplied together with or as part of other hardware, but may also be distributed in other forms, such as via the Internet or other wired or wireless telecommunication systems.

Any reference signs in the claims should not be construed as limiting the scope.

The present invention relates to an OLED device comprising an OLED and a short detection circuit for detection a short in the OLED. The short detection circuit comprises a temperature sensing unit for sensing a first and a second temperature of the OLED and a short detection unit for detecting the short based on a difference between the first and the second temperature. Therewith, the short detection can be less sensitive with respect to production tolerances resp. OLED binning.

1. An OLED device comprising:
an OLED, and
a short detection circuit for detecting a short in the OLED,
wherein the short detection circuit comprises:
a temperature sensing unit for sensing a first and a second temperature of the OLED, the temperature sensing unit comprising a first temperature sensor thermally coupled to the OLED at a first location thereof and a second temperature sensor thermally coupled to the OLED at a second location thereof, the second location being different from the first location, wherein the first temperature sensor is adapted to sense the first temperature at the first location and the second temperature sensor is adapted to sense the second temperature at the second location, and
a short detection unit for detecting the short based on a difference between the first and the second temperature, the short detection unit being adapted to detect the short if the difference between the first and the second temperature is changed more than a predefined value compared to an operation of the OLED in a thermal steady state without a short.

2. The OLED device as defined in claim 1, wherein the first temperature sensor is adapted to sense the first temperature at a first point in time and another first temperature at a second point in time, the second point in time being different from the first point in time.

3. The OLED device as defined in claim 2, wherein the short detection unit is adapted to detect the short if a time-temperature gradient corresponding to the difference between the first temperature and the another first temperature is changed more than a predefined value compared to an operation of the OLED in a thermal steady state without a short.

4. The OLED device as defined in claim 2, wherein the second temperature sensor is adapted to sense a second temperature of the OLED at a third point in time and another second temperature of the OLED at a fourth point in time, the fourth point in time being different from the third point in time, wherein the short detection unit is adapted to detect the short if at least one of a time-temperature gradient corresponding to the difference between the first temperature and the another first temperature and a time-temperature gradient corresponding to a difference between the second temperature and the another second temperature is changed more than a predefined value compared to an operation of the OLED in a thermal steady state without a short.

5.-6. (canceled)

7. The OLED device as defined in claim 1, wherein the first and second location are located such that a difference between a temperature of the OLED at the first location and a temperature of the OLED at the second location is larger than a predefined value during operation of the OLED in a thermal steady state without a short.

8. The OLED device as defined in claim 1, wherein the temperature sensing unit further comprises a third temperature sensor being thermally coupled to the OLED at a third location thereof, the third location being different from the first and the second location, wherein the third temperature sensor is adapted to sense a third temperature of the OLED at the third location, wherein the short detection unit is adapted to detect the short if at least one of the difference between the first and the second temperature and a difference between the first and the third temperature is changed more than a predefined value compared to an operation of the OLED in a thermal steady state without a short.

9. The OLED device as defined in claim 1, wherein the OLED comprises a substrate, a light-emitting layer, and an encapsulation encapsulating the light-emitting layer on the substrate, wherein the encapsulation comprises a cover lid attached to the substrate, and wherein the first location of the first temperature sensor is not located on the cover lid.

10. The OLED device as defined in claim 1, wherein the OLED comprises a substrate, a light-emitting layer, and an encapsulation encapsulating the light-emitting layer on the substrate, wherein the encapsulation is a thin-film encapsulation, and wherein the first location of the first temperature sensor is located on the thin-film encapsulation.

11. The OLED device as defined in claim 1, wherein the short detection circuit further comprises an ambient temperature sensing unit for sensing the ambient temperature of the OLED, and wherein the short detection unit is adapted to account for changes in the ambient temperature when detecting the short.

12. The OLED device as defined in claim 1, wherein the short detection circuit further comprises a short protection unit for being connected to a current source for providing a driving current to the OLED, wherein the short protection unit is adapted to switch off or reduce the driving current provided to the OLED in case the short is detected.

13. A lighting system comprising:
an OLED device as defined in claim 1, and
a current source for providing a driving current to the OLED.

14. A short detection circuit for detecting a short in an OLED, wherein the short detection circuit comprises:
a temperature sensing unit for sensing a first and a second temperature of the OLED, the temperature sensing unit comprising a first temperature sensor being thermally coupled to the OLED at a first location thereof, and a second temperature sensor being thermally coupled to the OLED at a second location thereof, the second location being different from the first location, wherein the first temperature sensor is adapted to sense the first temperature at the first location and the second temperature sensor is adapted to sense the second temperature at the second location, and
a short detection unit for detecting the short based on a difference between the first and the second temperature, the short detection unit being adapted to detect the short if the difference between the first and the second temperature is changed more than a predefined value compared to an operation of the OLED in a thermal steady state without a short.

15. A short detection method for detecting a short in an OLED, wherein the short detection method comprises:
sensing with a temperature sensing unit, a first temperature at a first location of the OLED and a second temperature at a second location of the OLED, by a temperature sensing unit, the second location being different from the first location, and
detecting with a short detection unit, the short if the difference between the first and the second temperature, is changed more than a predefined value compared to an operation of the OLED in a thermal steady state without a short.
